(19) United States
(12) Patent Application Publication
(10) Pub. No.: US 2023/0193511 A1
(43) Pub. Date: Jun. 22, 2023

(54) METHOD FOR TRANSFERRING A USEFUL LAYER OF CRYSTALLINE DIAMOND ONTO A SUPPORTING SUBSTRATE

(71) Applicant: Commissariat á l'Energie Atomique et aux Energies Alternatives, Paris (FR)

(72) Inventors: Cédric MASANTE, Grenoble Cedex 9 (FR); Lucie LE VAN-JODIN, Grenoble Cedex 9 (FR); Frédéric MAZEN, Grenoble Cedex 9 (FR); Frédéric MILESI, Grenoble Cedex 9 (FR)

(73) Assignee: Commissariat à l'Energie Atomique et aux Energies Alternatives, Paris (FR)

(21) Appl. No.: 18/063,752

(22) Filed: Dec. 9, 2022

(30) Foreign Application Priority Data
Dec. 16, 2021 (FR) 21 13702

(51) Int. Cl. C30B 33/06; C30B 31/22; C30B 29/02

(52) U.S. Cl. CPC C30B 33/06; C30B 31/22; C30B 29/02

(57) ABSTRACT

Method for transferring a useful layer onto a supporting substrate, comprising the successive steps:
a) providing a donor substrate made of crystalline diamond;
b) implanting gaseous species, through the first surface of the donor substrate, according to a given implantation dose and implantation temperature suitable for forming a graphitic flat zone;
c) assembling the donor substrate to the supporting substrate by direct adhesion;
d) applying thermal annealing according to a thermal budget suitable for fracturing the donor substrate along the graphitic flat zone; the annealing temperature being greater than or equal to 800° C.;
the implantation temperature is:
above a minimum temperature beyond which bubbling of the implanted gaseous species occurs on the first surface when the donor substrate is submitted, in the absence of a stiffening effect, to thermal annealing according to said thermal budget, below a maximum temperature beyond which the given implantation dose no longer allows formation of the graphitic flat zone.

### TECHNICAL FIELD

The invention relates to the technical field of transferring a useful layer of crystalline diamond onto a supporting substrate by Smart-Cut™ technology.

The invention notably finds application in the fabrication of power components, for example diodes of the Schottky type or power transistors, as well as in the fabrication of large diamond substrates by tessellation and epitaxial reworking.

### PRIOR ART

A method for transferring a useful layer of monocrystalline material (notably of silicon) onto a supporting substrate is known from the prior art, and comprises the successive steps:

a₀₁) providing a donor substrate, made of a monocrystalline material, and comprising a first surface;
b₀₁) implanting gaseous species, comprising ionized hydrogen atoms, through the first surface of the donor substrate, according to a given implantation dose suitable for forming a damaged flat zone within the donor substrate, the useful layer being delimited by the damaged flat zone and the first surface of the donor substrate;
c₀₁) assembling the donor substrate to the supporting substrate by direct adhesion with the first surface of the donor substrate;
d₀₁) applying thermal annealing to the assembly obtained at the end of step c₀₁), according to a thermal budget suitable for fracturing the donor substrate along the damaged flat zone, so as to expose the useful layer.

It is known from the prior art, notably from the documents A. A. Gippius et al., “Defect-induced graphitization in diamond implanted with light ions”, Phys. Rev. B Condens. Matter, Vol. 308-310, p. 573-576, 2001, R. A. Khmelnitskiy et al., “Blistering in diamond implanted with hydrogen ions”, Vacuum, Vol. 78, No. 2-4, p. 273-279, 2005, G. F. Kuznetsov, “Quantitative analysis of blistering upon annealing of hydrogen-ion-implanted diamond single crystals”, Tech. Phys., Vol. 51, No. 10, p. 1367-1371, 2006, V. P. Popov et al., “Conductive layers in diamond formed by hydrogen ion implantation and annealing”, Nuclear Inst. and Methods in Physics Research, B, Vol. 282, p. 100-107, 2012, that it is possible for a diamond donor substrate that has undergone an implantation step similar to step b₀₁) described above, to obtain bubbling of the implanted gaseous species in the first surface of the donor substrate when the donor substrate is submitted, in the absence of a stiffening effect, to thermal annealing according to a first thermal budget having an annealing temperature above 1300° C. Now, obtaining satisfactory bubbling in the absence of a stiffening effect makes it possible to envisage fracturing of the donor substrate along the damaged flat zone, in the presence of a stiffening effect (i.e. with the supporting substrate bonded), by applying thermal annealing according to the first thermal budget.

This method from the prior art is not entirely satisfactory insofar as said annealing temperature (above 1300° C.) is highly detrimental when the donor substrate and the supporting substrate, assembled in step c₀₁), have significantly different coefficients of thermal expansion (CTE). In fact, this may lead to the formation of defects (cracks), or even complete failure of the structure (breakage).

To overcome this problem, a method is known from the prior art for transferring a useful layer of diamond onto a supporting substrate, comprising the successive steps:

a₀₂) providing a donor substrate, made of crystalline diamond, and comprising a first surface;
b₀₂) implanting gaseous species, comprising ionized hydrogen atoms, through the first surface of the donor substrate, according to a given implantation dose suitable for forming a damaged flat zone within the donor substrate, the useful layer being delimited by the damaged flat zone and the first surface of the donor substrate;
c₀₂) applying thermal annealing to the donor substrate, according to a thermal budget with an annealing temperature between 800° C. and 1000° C., so as to transform the damaged flat zone at the end of step b₀₂) into a graphitic flat zone;
d₀₂) implanting gaseous species, comprising ionized hydrogen atoms, through the first surface of the donor substrate, at the level of the graphitic flat zone obtained at the end of step c₀₂);
e₀₂) assembling the donor substrate to the supporting substrate by direct adhesion with the first surface of the donor substrate;
f₀₂) applying thermal annealing to the assembly obtained at the end of step e₀₂), according to a thermal budget suitable for fracturing the donor substrate along the graphitic flat zone, so as to expose the useful layer; the thermal budget having an annealing temperature between 800° C. and 1000° C.

Said method from the prior art is not entirely satisfactory insofar as it is necessary to perform two implantations [step b₀₂) and step d₀₂)], as well as apply two thermal annealing steps [step c₀₂) and step f₀₂)], which greatly increases the operating time and the costs associated with implementation of this method. Moreover, localized (i.e. extending over a reduced portion of the first surface of the donor substrate) and uncontrolled bubbling of the gaseous species implanted in step b₀₂) might be observed on the first surface of the donor substrate at the end of step c₀₂). This localized bubbling is highly detrimental with respect to the direct adhesion in step e₀₂) because of the exfoliations that may occur.

A person skilled in the art will therefore try to find a solution for:

lowering the annealing temperature in step d₀₁),

performing a single implantation of the gaseous species in step b₀₁).

### DISCLOSURE OF THE INVENTION

The invention aims to remedy the aforementioned drawbacks wholly or partly. For this purpose, the invention relates to a method for transferring a useful layer onto a supporting substrate, comprising the successive steps:

a) providing a donor substrate, made of crystalline diamond, and comprising a first surface;
b) implanting gaseous species, comprising ionized hydrogen atoms, through the first surface of the donor substrate, according to a given implantation dose and a given implantation temperature suitable for forming a graphitic flat zone within the donor substrate, the useful layer being delimited by the graphitic flat zone and the first surface of the donor substrate;
c) assembling the donor substrate to the supporting substrate by direct adhesion with the first surface of the donor substrate;
d) applying thermal annealing to the assembly obtained at the end of step c), according to a thermal budget suitable for fracturing the donor substrate along the graphitic flat zone, so as to expose the useful layer; the thermal budget having an annealing temperature greater than or equal to 800° C.;

and in said method the given implantation temperature, designated T, complies with:

T>Tₘᵢₙ, where Tₘᵢₙ is a minimum temperature beyond which bubbling of the implanted gaseous species occurs on the first surface of the donor substrate when the donor substrate is submitted, in the absence of a stiffening effect, to thermal annealing according to a thermal budget identical to that in step d), Tₘᵢₙ being predetermined as a function of the given implantation dose; and
T<Tₘₐₓ, where Tₘₐₓ is a maximum temperature beyond which the given implantation dose no longer allows formation of the graphitic flat zone within the donor substrate.

Thus, said method according to the invention makes it possible, owing to step b), to apply a thermal annealing in step d) according to a thermal budget having an annealing temperature that can be well below those of the prior art. An annealing temperature below that of the prior art is less detrimental in terms of risk of failure of the structure or formation of defects (cracks) when the donor substrate and the supporting substrate possess significantly different coefficients of thermal expansion.

In contrast to the prior art, step b) is a single, hot implantation of the gaseous species through the first surface of the donor substrate, which makes it possible to reduce the density of defects that are generated.

The inventors found that step b) must be carried out at a temperature selected from a range of limited values, in order to permit fracture of the donor substrate along the graphitic flat zone in step d).

The given implantation temperature at which step b) is carried out is strictly above a minimum temperature (Tₘᵢₙ) beyond which bubbling of the implanted gaseous species occurs on the first surface of the donor substrate when the donor substrate is submitted, in the absence of a stiffening effect, to thermal annealing according to the thermal budget (moderated relative to the prior art) envisaged in step d). Bubbling of the implanted gaseous species must occur over an extent of the first surface of the donor substrate that is compatible with bonding by direct adhesion. Tₘᵢₙ is determined before carrying out a method according to the invention. In other words, preliminary experiments may be conducted to determine Tₘᵢₙ, consisting of submitting the donor substrate, in the absence of a stiffening effect, to thermal annealing according to a thermal budget identical to that envisaged in step d) in the context of carrying out a method according to the invention.

The given implantation temperature at which step b) is carried out is strictly lower than a maximum temperature (Tₘₐₓ) beyond which the given implantation dose no longer allows formation of the graphitic flat zone within the donor substrate. In fact, increasing the implantation temperature gives rise to an increase in the rate of recombination and/or healing of the defects. Thus, when T≥Tₘₐₓ, competition between the damage mechanisms (in the implantation conditions) and the mechanisms of ‘healing’ does not lead to formation of a layer (flat zone) that is sufficiently damaged to allow formation of the graphitic flat zone necessary for obtaining fracture.

These implantation conditions (dose and temperature) in step b) make it possible to obtain a graphitic flat zone rich in hydrogen atoms, which will be able to lead to fracture in step d), while avoiding double implantation and double thermal annealing of the prior art.

The method according to the invention may comprise one or more of the following characteristic features.

According to a characteristic feature of the invention, the thermal budget of the thermal annealing applied in step d) has an annealing temperature between 800° C. and 1200° C., preferably between 800° C. and 1100° C., more preferably between 850° C. and 1000° C.

Thus, one advantage provided by said thermal budget is to limit the mechanical stresses at the bonding interface, when the donor substrate and the supporting substrate possess significantly different coefficients of thermal expansion. These mechanical stresses may in fact cause premature detachment of the supporting substrate from the donor substrate before transfer takes place.

According to a characteristic feature of the invention, the thermal budget of the thermal annealing applied in step d) has an annealing time between 30 minutes and 7 hours, preferably between 45 minutes and 75 minutes.

According to a characteristic feature of the invention, the given implantation temperature at which step b) is carried out is strictly above 250° C., preferably strictly above 280° C.

Thus, an advantage provided is obtaining bubbling of the implanted gaseous species, in the absence of a stiffening effect, occurring over an extent of the first surface of the donor substrate that is compatible with bonding by direct adhesion.

According to a characteristic feature of the invention, the given implantation temperature at which step b) is carried out is strictly below 500° C.

According to a characteristic feature of the invention, the given implantation temperature at which step b) is carried out is strictly below 400° C., preferably strictly below 380° C.

According to a characteristic feature of the invention, step b) is carried out in such a way that the given implantation dose is strictly above 10¹⁷ at·cm⁻², preferably between 3.10¹⁷ at·cm⁻² and 4.10¹⁷ at·cm⁻².

Thus, an advantage provided is local amorphization of the crystalline diamond while preserving the crystalline quality of the useful layer.

According to a characteristic feature of the invention, the gaseous species are implanted in step b) according to an implantation energy above 30 keV.

Thus, the implantation energy will be adapted according to the thickness envisaged for the useful layer.

According to a characteristic feature of the invention, step b) is the only step of implantation of the gaseous species through the first surface of the donor substrate.

Thus, an advantage provided is limiting the operating time and the costs associated with carrying out the method.

According to a characteristic feature of the invention, the method comprises a step c′) consisting of applying thermal annealing to the assembly obtained at the end of step c), according to a thermal budget suitable for reinforcing the bonding interface between the first surface of the donor substrate and the supporting substrate without initiating fracture of the donor substrate along the graphitic flat zone; step c′) being carried out before step d), thermal annealing being applied in step d) to the assembly obtained at the end of step c′).

Thus, an advantage provided is increasing the energy of adhesion of the bonding interface.

According to a characteristic feature of the invention, step c) is preceded by a step c₀) consisting of forming a surface layer on the first surface of the donor substrate, step c₀) being carried out after step b), the surface layer being a layer of oxide or a metallic layer; the donor substrate being assembled to the supporting substrate in step c) by direct adhesion with the surface layer.

Thus, an advantage provided is improvement in the quality of bonding by direct adhesion between the donor substrate and the supporting substrate.

### Definitions

“Useful layer” means a layer starting from which a device may be formed for all kinds of applications, notably electronic, mechanical, optical, etc.
“Substrate” means a self-supporting physical support. A substrate may be a wafer, which is generally in the form of a disk obtained by cutting from an ingot of a crystalline material.
“Crystalline diamond” means the monocrystalline form or the polycrystalline form of diamond.
“Flat zone” means flatness within the usual tolerances connected with the experimental conditions of fabrication, and not perfect flatness in the mathematical sense of the term.
“Graphitic” means that the flat zone comprises a crystalline phase of graphite and an amorphous phase of carbon. The graphite of the crystalline phase may be nanocrystalline. The amorphous phase of carbon is free from crystalline structures.
“Direct adhesion” means spontaneous bonding resulting from bringing two surfaces directly into contact, i.e. in the absence of an additional element such as a glue, a wax, or brazing. The adhesion results principally from the van der Waals forces arising from the electronic interaction between the atoms or the molecules of two surfaces, hydrogen bonds from surface preparation or covalent bonds established between the two surfaces. It is also called bonding by molecular adhesion, or direct bonding.
“Thermal annealing” means a thermal treatment comprising:
   a phase of gradual increase in temperature (rising ramp) until a temperature called annealing temperature is reached,
   a holding phase (plateau) at the annealing temperature, for a time called annealing time,
   a cooling phase.
“Thermal budget” means energy supply of a thermal nature, determined by the choice of a value of the annealing temperature and the choice of a value of the annealing time.
“Stiffening effect” means the effect caused (in terms of stiffness conferred) by the presence of a supporting substrate assembled to the donor substrate, allowing transfer of the useful layer without development of blistering.
“Predetermined” means that Tₘᵢₙ is determined before carrying out a method according to the invention. Preliminary experiments may be conducted to determine Tₘᵢₙ, these experiments consisting of submitting the donor substrate, in the absence of a stiffening effect, to thermal annealing according to a thermal budget identical to that envisaged in step d) in the context of carrying out a method according to the invention.
“occurs on the first surface” means that the bubbling of the implanted gaseous species occurs, in the absence of a stiffening effect, over an extent of the first surface of the donor substrate that is compatible with bonding by direct adhesion.
The values X and Y expressed by means of the expressions “between X and Y” are included in the range of values defined.
“at.” denotes the term “atoms”.
“Surface layer” means a layer covering the first surface of the donor substrate.

### BRIEF DESCRIPTION OF THE DRAWINGS

Other features and advantages will appear in the detailed account of different embodiments of the invention, the account being provided with examples and references to the accompanying drawings.

FIGS. 1 (1a to 1e) comprises schematic sectional views illustrating steps of a first embodiment of a method according to the invention.

FIGS. 2 (2a to 2e) comprises schematic sectional views illustrating steps of a second embodiment of a method according to the invention.

FIGS. 3 (3a to 3e) comprises schematic sectional views illustrating steps of a third embodiment of a method according to the invention.

It should be noted that the drawings described above are schematic, and are not necessarily to scale, for legibility and to make them easier to understand. The sections are made along the normal to the first surface of the donor substrate.

### DETAILED ACCOUNT OF THE EMBODIMENTS

Elements that are identical or provide the same function will bear the same references for the various embodiments, for simplification.

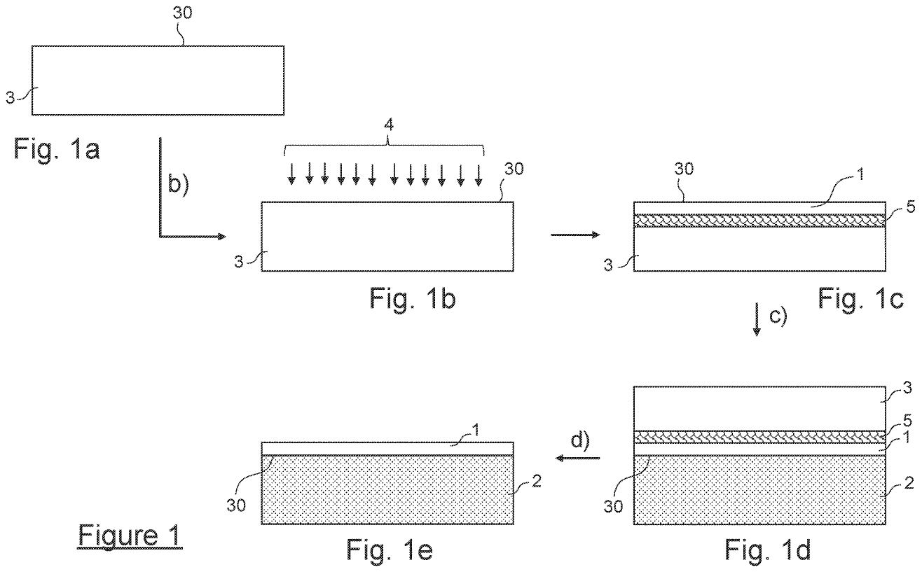

As illustrated in FIGS. 1 to 3, the invention relates to a method for transferring a useful layer 1 onto a supporting substrate 2, comprising the successive steps:

a) providing a donor substrate 3, made of crystalline diamond, and comprising a first surface 30;
b) implanting gaseous species 4, comprising ionized hydrogen atoms, through the first surface 30 of the donor substrate 3, according to a given implantation dose and a given implantation temperature suitable for forming a graphitic flat zone 5 within the donor substrate 3, the useful layer 1 being delimited by the graphitic flat zone 5 and the first surface 30 of the donor substrate 3;
c) assembling the donor substrate 3 to the supporting substrate 2 by direct adhesion with the first surface 30 of the donor substrate 3;
d) applying thermal annealing to the assembly obtained at the end of step c), according to a thermal budget suitable for fracturing the donor substrate 3 along the graphitic flat zone 5, so as to expose the useful layer 1.

The thermal budget of the thermal annealing applied in step d) has an annealing temperature greater than or equal to 800° C.

Step b) is carried out at the given implantation temperature, designated T, complying with:

T>Tₘᵢₙ, where Tₘᵢₙ is a minimum temperature beyond which bubbling of the implanted gaseous species 4 occurs on the first surface 30 of the donor substrate 3 when the donor substrate 3 is submitted, in the absence of a stiffening effect, to thermal annealing according to a thermal budget identical to that in step d), Tₘᵢₙ being predetermined as a function of the given implantation dose; and
T<Tₘₐₓ, where Tₘₐₓ is a maximum temperature beyond which the given implantation dose no longer allows formation of the graphitic flat zone 5 within the donor substrate 3.

### Step a)

Step a) is illustrated in FIGS. 1a, 2a, 3a.

The first surface 30 of the donor substrate 3 may have a surface area of the order of a few square millimetres. The first surface 30 of the donor substrate 3 may be oriented in terms of crystal planes according to the Miller indices [100]. As a non-limiting example, the donor substrate 3 may have a thickness of the order of 0.5 mm.

### Step b)

Step b) is illustrated in FIGS. 1b and 1c, 2b and 2c, 3b and 3c.

Step b) is the only implantation step of the gaseous species 4 through the first surface 30 of the donor substrate 3. In other words, the method according to the invention comprises a single step of implantation of the gaseous species 4 through the first surface 30 of the donor substrate 3. The method according to the invention advantageously does not have a step of implantation of non-gaseous species, before step c), in a zone of the donor substrate 3 corresponding to the graphitic flat zone 5.

The gaseous species 4 may comprise ionized helium atoms, in addition to the ionized hydrogen atoms. In other words, the ionized hydrogen atoms and the ionized helium atoms may be co-implanted in step b).

The given implantation temperature at which step b) is carried out is advantageously strictly above 250° C., preferably strictly above 280° C. In other words, Tₘᵢₙ is between 250° C. and 280° C.

The given implantation temperature at which step b) is carried out is preferably strictly below 500° C. The given implantation temperature at which step b) is carried out is advantageously strictly below 400° C., preferably strictly below 380° C. In other words, Tₘₐₓ is between 380° C. and 500° C., advantageously between 380° C. and 400° C.

Step b) is advantageously carried out in such a way that the given implantation dose is strictly above 10¹⁷ at·cm⁻², preferably between 3.10¹⁷ at·cm⁻² and 4.10¹⁷ at·cm⁻².

The gaseous species 4 are advantageously implanted in step b) according to an implantation energy above 30 keV. Step b) may be carried out in such a way that the useful layer 1 has a thickness between some tens of nanometres and some microns. “Thickness” means a dimension extending according to the normal to the first surface 30 of the donor substrate 3.

Step b) is advantageously carried out in such a way that the graphitic flat zone 5 extends over the entire surface area of the first surface 30 of the donor substrate 3, to a given depth of the first surface 30. The depth of the graphitic flat zone 5 (starting from the first surface 30 of the donor substrate 3) is mainly determined by the implantation energy.

### Step c)

Step c) is illustrated in FIGS. 1d, 2d and 3d.

Step c) may be preceded by steps consisting of cleaning or preparing the first surface 30 of the donor substrate 3 (more generally the surface to be bonded), for example to avoid contamination of the first surface 30 with hydrocarbons, particles or metallic elements. As a non-limiting example, it is possible to treat the first surface 30 by means of a dilute solution SC1 (mixture of NH₄OH and H₂O₂) in order to generate chemical surface bonds able to provide good adhesion.

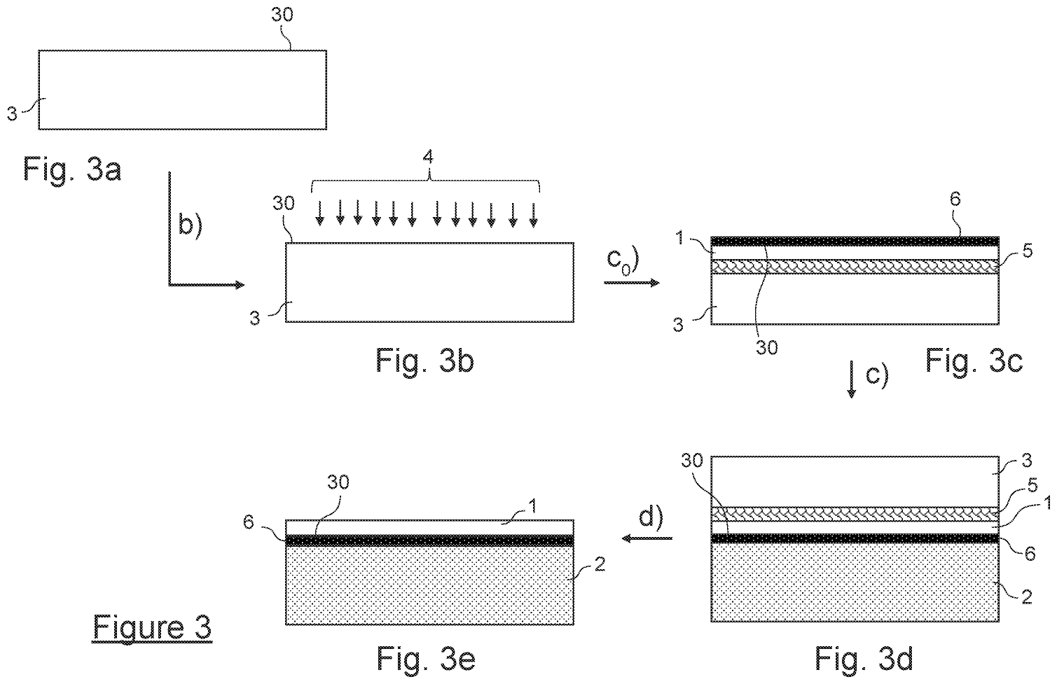

As illustrated in FIG. 3c, step c) may be preceded by a step c₀) consisting of forming a surface layer 6 on the first surface 30 of the donor substrate 3. Step c₀) is carried out after step b). The surface layer 6 is advantageously a layer of oxide or a metallic layer. The surface layer 6 has the role of facilitating subsequent bonding. The layer of oxide may consist of SiO₂. The metallic layer may be made of a metallic material selected from Ti, W. The surface layer 6 may have a thickness between some nanometres and 1 μm.

Step c) is carried out at a suitable temperature and a suitable pressure depending on the type of bonding employed.

If there is a surface layer 6 covering the first surface 30 of the donor substrate 3, the donor substrate 3 is assembled to the supporting substrate 2 in step c) by direct adhesion with the surface layer 6.

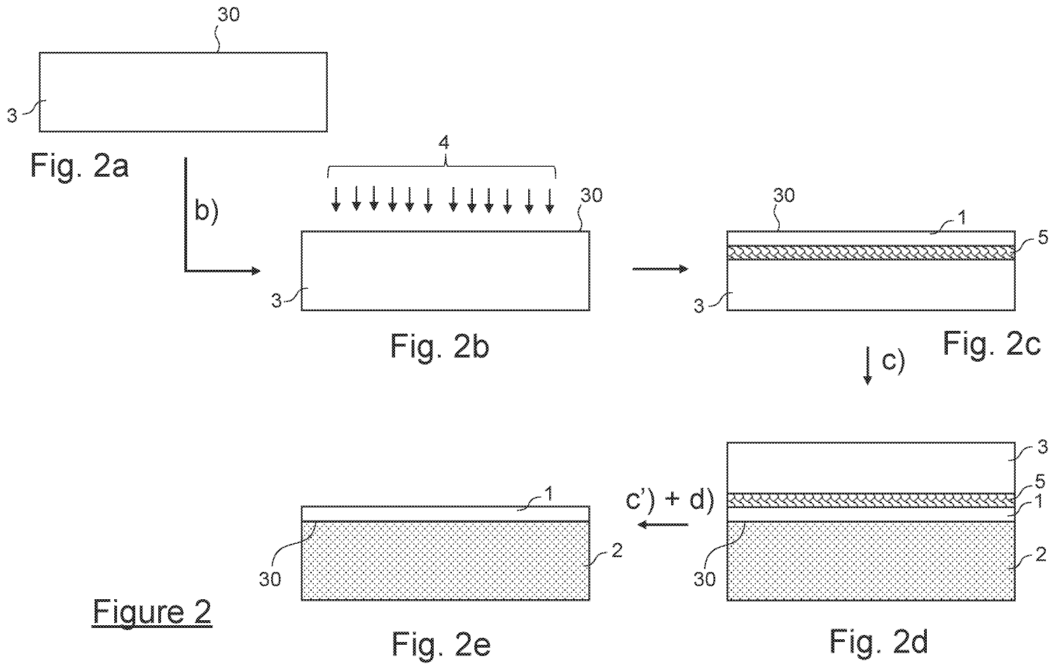

In the embodiment illustrated in FIG. 2, the method advantageously comprises a step c′) consisting of applying thermal annealing to the assembly obtained at the end of step c), according to a thermal budget suitable for reinforcing the bonding interface between the first surface 30 of the donor substrate 3 and the supporting substrate 2 without initiating fracture of the donor substrate 3 along the graphitic flat zone 5. Step c′) is carried out before step d). The thermal budget for reinforcing the bonding interface is advantageously less than 10% of the thermal budget for fracture, i.e. the thermal budget applied in step d). It is possible to define a percentage of the thermal budget for fracture. The thermal budget for fracture may be described by a law of the Arrhenius type, relating the fracture time (designated “t”) to the annealing temperature (designated “Tᵣ”, in kelvin):

$$t = A exp ( - {E}_{a} / {kT}_{r} )$$

where:

“A” is a constant,

“Eₐ” is a constant corresponding to the energy of activation of the mechanism involved in fracture,

“k” is the Boltzmann constant.

“Eₐ” can be determined experimentally starting from two operating points: it is the slope of the straight line “log(t)” as a function of “1/kTᵣ”.

“Eₐ” being known, it is easy to determine, for a given annealing temperature “Tᵣ₁”, the time “t₁” required to obtain fracture. By convention, it will be said that the percentage of the thermal budget used corresponds to the percentage of the time “t₁” elapsed at temperature “Tᵣ₁”. Thus, for example, to remain at less than 10% of the thermal budget for fracture, a time “t” less than “t₁/10” will be selected for thermal annealing at an annealing temperature “Tᵣ₁”.

The method according to the invention advantageously does not have a step of thermal treatment of the donor substrate 3 obtained at the end of step b), carried out before step c) of assembly to the supporting substrate 2. In other words, the method according to the invention advantageously does not have a step of thermal treatment carried out between step b) and step c).

As a non-limiting example, the supporting substrate 2 may be made of a material selected from Si, SiC, GaN, polycrystalline diamond.

### Step d)

Step d) is illustrated in FIGS. 1e, 2e and 3e.

The thermal budget of the thermal annealing applied in step d) advantageously has an annealing temperature between 800° C. and 1200° C., preferably between 800° C. and 1100° C., more preferably between 850° C. and 1000° C.

The thermal budget of the thermal annealing applied in step d) advantageously has an annealing time between 30 minutes and 7 hours, preferably between 45 minutes and 75 minutes.

If step c′) is carried out, thermal annealing is applied in step d) to the assembly obtained at the end of step c′).

Step d) is advantageously carried out in an environment with a controlled atmosphere in order to limit the presence of oxygen, which consumes crystalline diamond by forming oxides (CO, CO₂). As a non-limiting example, step d) may be carried out under high vacuum, such as ultrahigh vacuum below 10⁻⁵ mbar or under a neutral atmosphere (e.g. argon).

### Embodiment Example

The first surface 30 of the donor substrate 3, provided in step a), of monocrystalline diamond, is oriented in terms of crystal planes according to the Miller indices [100]. The donor substrate 3 has a thickness of 0.5 mm. The first surface 30 of the donor substrate 3 has a surface area of 4×4 mm².

Step b) is carried out according to the following conditions:

the given implantation dose is equal to 3.7.10¹⁷ cm⁻²;

the implantation energy is equal to 150 keV;

the implantation temperature is equal to 283° C.

The graphitic flat zone 5 formed at the end of step b) has a thickness of the order of 100 nm, and is located at a depth of the first surface 30 of the order of 800 nm

Step d) is carried out at an annealing temperature of 1000° C. for 60 minutes.

The invention is not limited to the embodiments presented. A person skilled in the art is able to consider their technically operative combinations, and substitute them with equivalents.

1. A method for transferring a useful layer onto a supporting substrate, comprising the successive steps:
a) providing a donor substrate, made of crystalline diamond, and comprising a first surface;
b) implanting gaseous species, comprising ionized hydrogen atoms, through the first surface of the donor substrate, according to a given implantation dose and a given implantation temperature designed to form a graphitic flat zone within the donor substrate, the useful layer being delimited by the graphitic flat zone and the first surface of the donor substrate;
c) assembling the donor substrate to the supporting substrate by direct adhesion with the first surface of the donor substrate;
d) applying thermal annealing to the assembly obtained at the end of step c), according to a thermal budget designed to fracture the donor substrate along the graphitic flat zone, so as to expose the useful layer; the thermal budget having an annealing temperature greater than or equal to 800° C.;
wherein the given implantation temperature, designated T, complies with:
T>Tₘᵢₙ, where Tₘᵢₙ is a minimum temperature beyond which bubbling of the implanted gaseous species occurs on the first surface of the donor substrate when the donor substrate is submitted, in the absence of a stiffening effect, to thermal annealing according to a thermal budget identical to that in step d), Tₘᵢₙ being predetermined as a function of the given implantation dose, the given implantation temperature at which step b) is carried out being strictly above 250° C.; and
T<Tₘₐₓ, where Tₘₐₓ is a maximum temperature beyond which the given implantation dose no longer allows formation of the graphitic flat zone within the donor substrate.

2. The method according to claim 1, wherein the thermal budget of the thermal annealing applied in step d) has an annealing temperature between 800° C. and 1200° C.

3. The method according to claim 1, wherein the thermal budget of the thermal annealing applied in step d) has an annealing time between 30 minutes and 7 hours.

4. The method according claim 1, wherein the given implantation temperature at which step b) is carried out is strictly below 500° C.

5. The method according to claim 1, wherein the given implantation temperature at which step b) is carried out is strictly below 400° C.

6. The method according to claim 1, wherein step b) is carried out in such a way that the given implantation dose is strictly above 10¹⁷ at·cm⁻².

7. The method according to claim 1, wherein the gaseous species are implanted in step b) according to an implantation energy above 30 keV.

8. The method according to claim 1, wherein step b) is the only implantation step of the gaseous species through the first surface of the donor substrate.

9. The method according to claim 1, comprising a step c′) consisting of applying thermal annealing to the assembly obtained at the end of step c), according to a thermal budget designed to reinforce the bonding interface between the first surface of the donor substrate and the supporting substrate without initiating fracture of the donor substrate along the graphitic flat zone;
step c′) being carried out before step d), thermal annealing being applied in step d) to the assembly obtained at the end of step c′).

10. The method according to claim 1, wherein step c) is preceded by a step c₀) consisting of forming a surface layer on the first surface of the donor substrate, step c₀) being carried out after step b), the surface layer being a layer of oxide or a metallic layer; the donor substrate being assembled to the supporting substrate in step c) by direct adhesion with the surface layer.
